(19) United States
(12) Patent Application Publication
(10) Pub. No.: US 2022/0077842 A1
(43) Pub. Date: Mar. 10, 2022

(54) INTEGRATION METHOD AND INTEGRATION STRUCTURE FOR CONTROL CIRCUIT AND BULK ACOUSTIC WAVE FILTER

(71) Applicant: NINGBO SEMICONDUCTOR INTERTIONAL CORPORATION (SHANGHAI BRANCH), Shanghai (CN)

(72) Inventor: Xiaoshan QIN, Ningbo, Zhejiang (CN)

(21) Appl. No.: 17/417,961

(22) PCT Filed: Nov. 13, 2019
(86) PCT No.: PCT/CN2019/117795

§ 371 Date: Jun. 24, 2021

(30) Foreign Application Priority Data
Dec. 26, 2018 (CN) 201811601419.7

(51) Int. Cl. H03H 9/17; H03H 3/02; H03H 9/54

(52) U.S. Cl. CPC H03H 9/173; H03H 2003/021; H03H 9/54; H03H 3/02

(57) ABSTRACT

The present disclosure provides an integration method and integration structure for a control circuit and a Bulk Acoustic Wave (BAW) filter. The integration method includes: providing a base, the base being provided with a control circuit: forming a first cavity on the base; providing a BAW resonating structure, an input electrode and an output electrode being arranged on a surface of the BAW resonating structure, and the BAW resonating structure including a second cavity; facing the surface of the BAW resonating structure towards the base, such that the BAW resonating structure is bonded to the base and seals the first cavity; and electrically connecting the control circuit to the input electrode and the output electrode. The present disclosure implements the control of the control circuit on the BAW filter by forming the control circuit and the cavity, required by the BAW filter, on the base, and then mounting the existing BAW resonating structure in the cavity, and thus may avoid the problems of the complex electrical connection process, large insertion loss and the like due to a fact that the existing BAW filter is integrated to the Printed Circuit Board (PCB) as a discrete device, has the high level of integration, and reduces the process cost.

### FIELD OF TECHNOLOGY

The present disclosure relates to the technical field of acoustic wave filters, and in particular to an integration method and integration structure for a control circuit and a Bulk Acoustic Wave (BAW) filter.

### BACKGROUND

The BAW filter is a device which implements electrical filtration based on the BAW theory by using acoustic resonance. It filters the resonance in the vertical direction through piezoelectric layers (AlN, ZnO and the like) between electrodes. The cavity BAW filter is the most successfully applied BAW filter at present. The main body structure of the cavity BAW filter is of a sandwich structure composed of an upper electrode, a piezoelectric layer and a lower electrode; and a cavity is respectively provided on two sides of the upper electrode and the lower electrode. When the acoustic signal travels to the top end of the upper electrode and the bottom end of the lower electrode, the acoustic wave is totally reflected due to the huge difference in acoustic impedance. Such a BAW filter has the small acoustic leak and may implement the high-Q value of the device.

When packaged, the single BAW filter is typically packaged as a discrete device, and then integrated. to a Printed Circuit Board (PCB). For the sake of the use requirement, it is frequent that a plurality of BAWs are integrated on one PCB hoard. Such a manner that performs independent packaging and then system integration leads to problems of the complex System In Package (SIP) wiring, large insertion loss and the like; and moreover, there is a need to introduce the discrete switch, selection device and control device for controlling the BAW filter, which accelerates both the process complexity and the manufacturing cost.

### SUMMARY

An objective of the present disclosure is to provide an integration method for a control circuit and a BAW filter and a corresponding integration structure, to overcome problems of the complex SIP wiring, large insertion loss and the like of the existing BAW filter during packaging and integration.

According to an aspect of the present disclosure, an integration method for a control circuit and a BAW filter is provided, which includes:

providing a base, the base being provided with a control circuit;

forming a first cavity on the base;

providing a BAW resonating structure, an input electrode and an output electrode being arranged on a surface of the BAW resonating structure, and the BAW resonating structure comprising a second cavity;

facing the surface of the BAW resonating structure towards the base, such that the BAW resonating structure is bonded to the base and seals the first cavity; and

electrically connecting the control circuit to the input electrode and the output electrode.

Optionally, the base includes a substrate and a first dielectric layer formed on the substrate; and

forming the first cavity on the base comprises:

forming the first cavity in the first dielectric layer,

Optionally, the substrate includes one of a Silicon-on-Insulator (SOI) substrate, a silicon substrate, a germanium substrate, a germanium silicate substrate and a gallium arsenide substrate.

Optionally, the control circuit includes a device structure and a first interconnection structure layer electrically connected to the device structure, the first interconnection structure layer being located on the first dielectric layer, and electrically connected to the input electrode and the output electrode.

Optionally, the device structure includes a Metal Oxide Semiconductor (MOS) device.

Optionally, electrically connecting the control circuit to the input electrode and the output electrode includes:

after bonding the BAW resonating structure, electrically connecting the first interconnection structure layer to the input electrode and the output electrode; or

before bonding the BAW resonating structure, forming a first redistribution layer and a first pad on the first interconnection structure layer; and

after bonding the BAW resonating structure, electrically connecting the first pad to the input electrode and the output electrode, such that the input electrode and the output electrode are electrically connected to the control circuit through the first pad and the first redistribution layer.

Optionally, facing the surface of the BAW resonating structure towards the base, such that the B,AW resonating structure is bonded to the base and seals the first cavity comprises:

forming an adhesion structure on the surface of the base and at the periphery of the first cavity; and

adhering the BI-resonating structure to the base through the adhesion structure.

Optionally, the adhesion structure includes a dry film.

Optionally, the first cavity is formed in the dry film by exposure and development

Optionally, the adhesion structure is formed by a patterned adhesive layer through screen printing.

Optionally, the integration method further includes: forming a second redistribution layer on a back of the base, the second redistribution layer being electrically connected to the input electrode, the output electrode and the control circuit.

Optionally, the second redistribution layer includes an Input/Output (I/O)pad.

Optionally, after the bonding, the integration method further includes:

forming a packaging layer, the packaging layer covering the base and the BAW resonating structure.

Optionally, the integration method further includes:

forming a third redistribution layer on the packaging layer, the third redistribution layer being electrically connected to the input electrode, the output electrode and the control circuit.

Optionally, both the input electrode and the output electrode include a pad.

According to another aspect of the present disclosure, an integration structure for a control circuit and a BAW filter is provided, which includes:

a base, the base being provided with a control circuit and a first cavity; and

a BAW resonating structure, an input electrode and an output electrode being arranged on a surface of the BAW resonating structure, the BAW resonating structure comprising a second cavity, and the surface of the BAW resonating structure facing towards the base such that the BAW resonating structure is bonded to the base and seals the first cavity, wherein

the control circuit is electrically connected to the input electrode and the output electrode.

Optionally, the base includes a substrate and a first dielectric layer formed on the substrate; and the first cavity is formed in the first dielectric layer; or

the base and the BAW resonating structure are bonded through an adhesion structure, and the first cavity is formed in the adhesion structure.

Optionally, the adhesion structure is a dry film.

Optionally, the substrate includes one of an SOI substrate, a silicon substrate, a germanium substrate, a germanium silicate substrate and a gallium arsenide substrate.

Optionally, the control circuit includes a device structure and a first interconnection structure layer electrically connected to the device structure, the first interconnection structure layer being located on the first dielectric layer, and electrically connected to the input electrode and the output electrode.

Optionally, the device structure includes an MOS device.

Optionally, a first redistribution layer and a first pad are formed on the base, the first pad being electrically connected to the input electrode and the output electrode, such that the input electrode and the output electrode are electrically connected to the control circuit through the first pad and the first redistribution layer.

Optionally, the integration structure further includes a second redistribution layer formed on a back of the base, the second redistribution layer being electrically connected to the input electrode, the output electrode and the control circuit.

Optionally, the second redistribution layer includes an I/O pad.

Optionally, the integration structure further includes a packaging layer, the packaging layer covering the base and the BAW resonating structure.

Optionally, the integration structure further includes a third redistribution layer formed on the packaging layer, the third redistribution layer being electrically connected to the input electrode, the output electrode and the control circuit.

Optionally, both the input electrode and the output electrode include a pad.

The present disclosure has the following beneficial effects: the present disclosure implements the control of the control circuit on the BAW filter by forming the control circuit and the cavity, required by the BAW filter, on the base, and then mounting the existing BAW resonating structure in the cavity, and thus may avoid the problems of the complex electrical connection process, large insertion loss and the like due to a fact that the existing BAW filter is integrated to the PCB as a discrete device, has the high level of integration, and reduces the process cost.

The present disclosure has other characteristics and advantages. These characteristics and advantages will become apparent from the accompanying drawings and following specific embodiments incorporated into the specification, or will be described in detail in the accompanying drawings and following specific embodiments incorporated into the specification. The accompanying drawings and the specific embodiments serve to explain a specific principle of the present disclosure.

### BRIEF DESCRIPTION OF THE DRAWINGS

By describing the exemplary embodiments of the present disclosure below in more detail in combination with the accompanying drawings, the above and other objectives, characteristics and advantages of the present disclosure will be more apparent. In the exemplary embodiments of the present disclosure, the same reference sign typically represents the same component.

FIG. 1 to FIG. 7 respectively show each process of an integration method for a control circuit and a BAW filter according to a first embodiment of the present disclosure.

FIG. 8 to FIG. 10 respectively show each process of an electrical connection for forming a BAW resonating structure in an integration method for a control circuit and a RAW filter according to a second embodiment of the present disclosure.

### IN THE FIGURES

101-silicon substrate, 102-insulating layer, 103-top silicon layer, 201-source, 202-drain, 203-gate. 204-gate dielectric layer, 301-first support plate. 302-second support plate, 303-first electrode, 304-second electrode, 305-piezoelectric layer, 306-silicon wafer, 307-second cavity, 401-first dielectric layer, 402-first cavity, 403-packaging layer, 404-first conductive post, 405-first wiring layer, 406-first redistribution layer, 407-first pad, 408-adhesion structure, 409-third redistribution layer, 410-second conductive post, 411-I/O pad, 501-third conductive post, 502-second wiring layer, and 503-second redistribution layer.

### DESCRIPTION OF TILE EMBODIMENTS

The present disclosure will be described below in more detail with reference to the accompanying drawings. Although the preferred embodiments of the present disclosure are shown in the accompanying drawings, it should be understood that the present disclosure may be implemented in various forms and should not be limited by the embodiments elaborated herein. Rather, these embodiments are provided so that the present disclosure will be thorough and complete, and the scope of the present disclosure can be fully conveyed to a, person skilled in the art.

In order to solve the problems of the complex wiring, large insertion loss and the like of the existing BAW filter during packaging and integration, the embodiments of the present disclosure provide an integration method and integration structure for a control circuit and a BAW filter.

The integration method for the control circuit and the BAW filter according to the embodiments of the present disclosure includes the following steps:

A base is provided, the base being provided with a control circuit; a first cavity is formed on the base; a BAW resonating structure is provided, an input electrode and an output electrode being arranged on a surface of the BAW resonating structure, and the BAW resonating structure including a second cavity; the surface of the BAW resonating structure faces towards the base, such that the BAW resonating structure is bonded to the base and seals the first cavity; and the control circuit is electrically connected to the input electrode and the output electrode.

The packaging method according to the embodiments of the present disclosure implements the control of the control circuit on the BAW filter by forming the control circuit and the first cavity, required by the BAW filter, on the base, and then mounting the existing BAW resonating structure in the first cavity, and thus may avoid the problems of the complex electrical connection process, large insertion loss and the like due to a fact that the existing BAW filter is integrated to the PCB as a discrete device, has the high level of integration, and reduces the process cost.

In order to understand the above objectives, characteristics and advantages of the present disclosure more clearly, the specific embodiments of the present disclosure will he described below in detail in combination with the accompanying drawings. When the embodiments of the present disclosure are detailed, the exemplary drawings are not partially amplified according to a general proportion for the ease of description. Moreover, the schematic diagrams are merely exemplary, and should not limit the scope of protection of the present disclosure herein. Additionally, three-dimensional spatial sizes on the length, width and length should be included in actual manufacture,

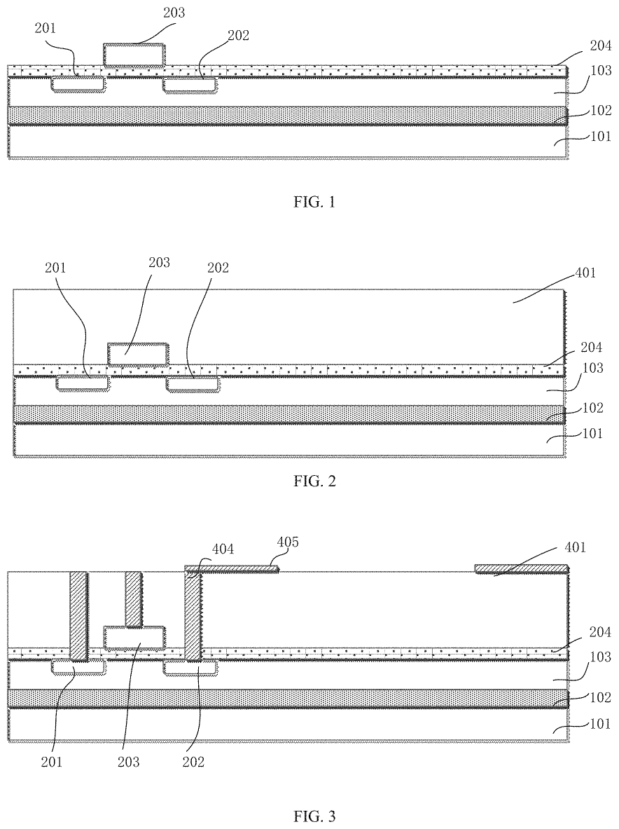

FIG. 1 to FIG, 7 respectively show each process of an integration method for a. control circuit and a BAW filter according to a first embodiment of the present disclosure. The integration method includes the following steps:

S1: referring to FIG. 1 to FIG. 4, a base is provided, the base being provided with a control circuit.

Referring to FIG. I and FIG. 2, in the embodiment, the base includes a substrate and a first dielectric layer 401 formed on the substrate. Optionally, the substrate includes one of an SOI substrate, a silicon substrate, a germanium substrate, a germanium silicate substrate and a gallium arsenide substrate. The person skilled in the art may also select the type of the substrate according to the control circuit formed on the substrate. In the embodiment, the substrate is the SOI substrate.

The SOI may be of a double-layer structure of the SOI substrate and the top monocrystalline silicon layer, and may also be of a sandwich structure with the insulating layer as the intermediate layer (called the buried layer). During device manufacture, only the top thin silicon layer serves as the device manufacturing layer to form structures like the source, drain and channel region, while the silicon substrate only takes the support effect. In the sandwich structure, the buried layer separates the device manufacturing layer from the silicon substrate electrically, so as to reduce the influence of the silicon substrate on the device performance. The SOI has the advantages of reducing the parasitic capacitance, reducing the power consumption, eliminating the latch-up effect and the like in device performance. At present, the SOI substrate is typically obtained with the Smart-cut™ process. The SOI substrate is used in the embodiment so as to exert the above advantages of the SOI.

Still referring to FIG. 1, in the embodiment, the SO1 substrate includes a silicon substrate 101, an insulating layer 102 located on the silicon substrate 101 and a top silicon layer 103 located on the insulating layer 102, or the 501 substrate may be of a double-layer structure of the insulating layer and the top silicon layer.

Still referring to FIG. 2, the first dielectric layer 401 is a low-K dielectric material layer such as a silicon oxide layer. The first dielectric layer 401 may be formed by Chemical Vapor Deposition (CVP). The first dielectric layer 401 is configured to form the first cavity 402 that is required by the work of the BAW filter.

In the embodiment, the control circuit includes a device structure and a first interconnection structure layer electrically connected to the device structure, the first interconnection structure layer being located on the first dielectric layer 401. The device structure includes an MOS device such as an MOS switch. The MOS switch may be the nMOS or pMOS switch. Still referring to FIG. 1, the MOS switch includes a source 201, a drain 202 and a gate 203, and further includes a gate dielectric layer 204 or a gate dielectric region on a surface of the top silicon layer 103 for isolating the source, drain and gate. The source 201 and the drain 202 may be formed in the top silicon layer with the Low Dose Drain (LDD) process and Source/Drain implantation (S/D IMP).

Referring to FIG. 3. optionally, the first interconnection structure layer includes a first conductive post 404 and a first wiring layer 405 that are electrically connected to the device structure in sequence. In the embodiment, a first through hole penetrating through the first dielectric layer 401 and a first trench provided on a surface of the first dielectric layer are first formed; and then, an electrical connection material is filled in the first through hole and the first trench to form the first conductive post 404 and the first wiring layer 405,

The first through hole penetrating through the first dielectric layer 401 and the first trench provided on the surface of the first dielectric layer 401 may be formed by etching. The first trench defines the path of local interconnection metal, Then, the electrical connection material is filled in the first through hole and the first trench by deposition (for example, sputtering). The electrical connection material is preferably copper, tungsten, titanium, etc. In the embodiment, as the gate dielectric layer 204 is formed on the top silicon layer 103, the first through hole further penetrates through the gate dielectric layer 204.

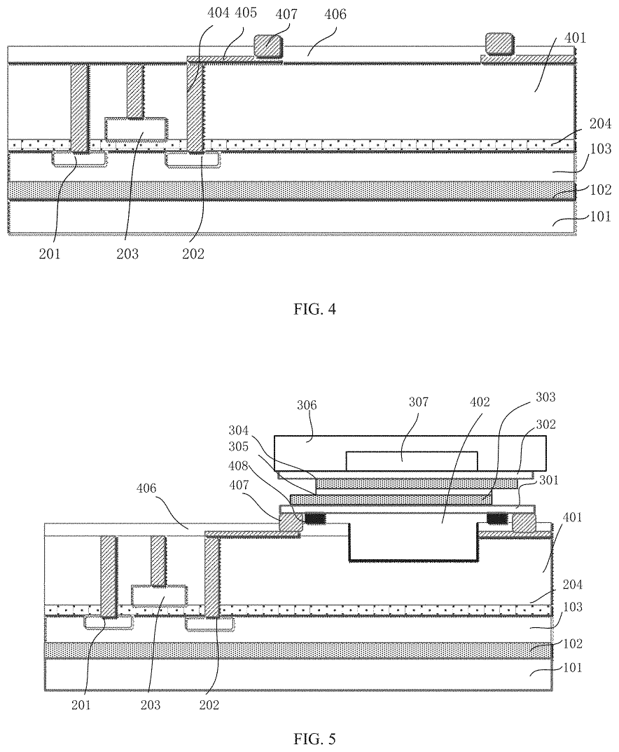

Referring to FIG. 4, optionally, in a case where the first interconnection structure layer cannot be directly and electrically connected to the input electrode and the output electrode, a first redistribution layer 406 and a first pad 407 are formed on the base, the first redistribution layer 406 being electrically connected to the first wiring layer 405 of the control circuit. The first redistribution layer 406 may be formed by deposition; and similarly, the first pad 407 is formed by etching and deposition.

S2: referring to FIG. 5, a first cavity is formed on the base.

Referring to FIG. 5, in the embodiment, the first cavity 402 that is sunken inwards is formed on the first dielectric layer 401. by etching.

Still referring to FIG. 5, optionally, an adhesion structure 408 is formed on a surface of the base, so as to implement subsequent bonding between the B,AW resonating structure and the base, The adhesion structure 408 may be a dry film or another type of chip connection film. Optionally, before the first cavity is formed on the base, in heating and pressurizing conditions, a layer of dry film is adhered on the surface of the base, the dry film is then patterned, and by performing exposure and development on the dry film, etching the first dielectric layer 401 and forming the first cavity 402 that is sunken inwards on the base, the retained dry film portion is formed into the adhesion structure 408. Optionally, the adhesion structure 408 is formed by a patterned adhesive layer through screen printing. The adhesive layer is typically made of epoxy resin. With the screen printing method, the patterned adhesive layer may be directly formed on the surface of the base, and there is no need for photoetching, exposure, development and other steps to implement the patterning. Optionally, when the first redistribution layer 406 is formed on the base, before the first cavity is formed on the base, in the heating and pressurizing conditions, a layer of dry film is adhered on a surface of the first redistribution layer 406, then the dry film is patterned, and by etching the dry film and the first dielectric layer 401 and forming the first cavity 402 that is sunken inwards on the base, the retained dry film portion is formed into the adhesion structure 408.

Optionally, when the first cavity 402 has a small depth, the first cavity 402 may be formed in the adhesion structure 408.

S3: referring to FIG. 5, a BAW resonating structure is provided, an input electrode and an output electrode being arranged on a surface of the BAW resonating structure, and the BAW resonating structure including a second cavity.

As shown in FIG. 5, the BAW resonating structure includes a first support plate 301, a second support plate 302, a first electrode 303 and a second electrode 304 arranged between the first support plate 301 and the second support plate 302, and a piezoelectric layer 305 disposed between the first electrode 303 and the second electrode 304. The input electrode and the output electrode (not shown) are arranged on an outer side of the first support plate 301, The input electrode and the output electrode are respectively and electrically connected to the first electrode 303 and the second electrode 304. Additionally, in order to ensure the normal work of the BAW filter, a silicon wafer 306 is disposed on an outer side of the second support plate 302. The second cavity 307 is provided on the silicon wafer 306. Upon integration, the second cavity 307 servers as the lower cavity typically referred in the art, and the first cavity 402 serves as the upper cavity typically referred in the art.

The first electrode 303 and the second electrode 304 may be made of Mo, Al and the like, with the thickness typically being 100 inn to 200 nm. The piezoelectric layer 305 is typically made of lead zirconate titanate piezoelectric ceramic (PZT), ZnO or AlN, with the thickness typically being 1 um to 2 μm. The first support plate 301 and the second support plate 302 are typically made of Si₃N₄ and AlN, and have the high mechanical strength, stable chemical performance, high acoustic velocity and little influence on the central frequency. The first support plate 301 and the second support plate 302 typically have a thickness of 100 nm to 200 nm,

S4: referring to FIG. 5, the surface of the BAW resonating structure faces towards the base, such that the BAW resonating structure is bonded to the base and seals the first cavity.

Optionally, the annular adhesion structure 408 is formed on the surface of the base and at the periphery of the first cavity 402. The first support plate 301 of the BAW resonating structure is adhered on the base through the adhesion structure 408, such that the BAW resonating structure is bonded to the base and seals the first cavity 402,

S5: the control circuit is electrically connected to the input electrode and the output electrode.

It is mentioned in step S1 that the control circuit may include the device structure and the first interconnection structure layer electrically connected to the device structure, the first interconnection structure layer being located on the first dielectric layer 401. Correspondingly, electrically connecting the control circuit to the input electrode and the output electrode includes after the BAW resonating structure is bonded, the first interconnection structure layer is electrically connected to the input electrode and the output electrode,

Still referring to FIG, 5, optionally, the first redistribution layer 406 and the first pad 407 may be formed on the base; and correspondingly, electrically connecting the control circuit to the input electrode and the output electrode includes:

Before the BAW resonating structure is bonded, the first redistribution layer 406 and the first pad 407 are formed on the first interconnection structure layer.

After the BAW resonating structure is bonded, the first pad 407 is electrically connected to the input electrode and the output electrode, such that the input electrode and the output electrode are electrically connected to the control circuit through the first pad 407 and the first redistribution layer 406.

The integration for the control circuit and the BAW filter is implemented through the above steps S1 to S5. In the embodiment, the integration method may further include the following steps S6-S8:

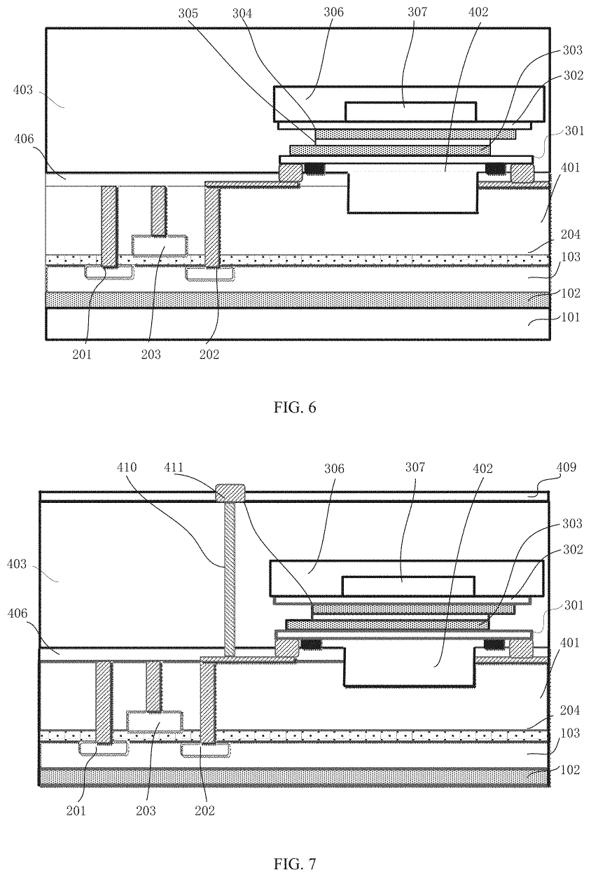

S6: referring to FIG. 6, a packaging layer 403 is formed, the packaging layer covering the base and the &kW resonating structure. The packaging layer 403 may be formed with a molding method. The material used by the molding may be epoxy resin.

S7: referring to FIG. 7. the silicon substrate 101 is removed to make the integration structure thin, in the embodiment, the silicon substrate 101 may be removed by Chemico-Mechanical Polishing (CMP).

S8: still referring to FIG. 7, a third redistribution layer 409 is formed on the packaging layer 403, the third redistribution layer 409 being electrically connected to the input electrode, the output electrode and the control circuit.

Specifically, a second through hole penetrating through the packaging layer 403 is formed, the electrical connection material is filled in the second through hole to form a second conductive post 410, and then the third redistribution layer 409 is formed on the packaging layer 403. The third redistribution layer 409 is electrically connected to the second conductive post 410. The third redistribution layer 409 further includes an I/O pad 411. Similarly, the second through hole may be formed by etching; and the electrical connection material (such as copper) is filled in the second through hole by deposition (for example, sputtering) to form the second conductive post 410, The I/O pad 411 may be connected to an external power supply.

The integration structure obtained in the embodiment is as shown in FIG, 7,

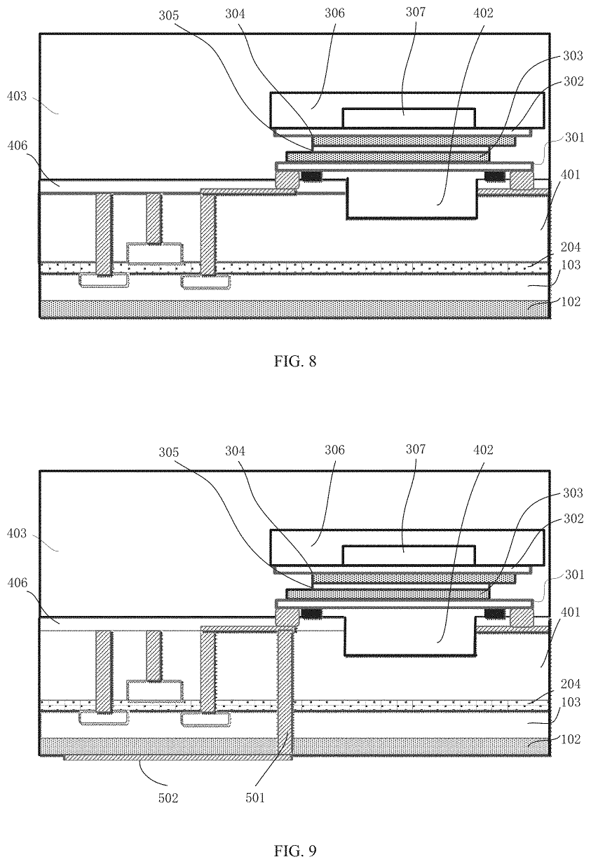

The integration method for the control circuit and the RAW filter according to the second embodiment of the present disclosure also includes the above steps S1 to S7, and the difference from the first embodiment lies in step S8. Referring to FIG. 8 to FIG. 10, the integration method according to the second embodiment of the present disclosure includes the following step after step S7:

A second redistribution layer 502 is formed on a back of the base, the second redistribution layer 502 being electrically connected to the input electrode, the output electrode and the control circuit.

Specifically, referring to FIG. 8 and FG. 9, in the integration structure, in which the packaging layer 403 is formed and the silicon substrate 101 is removed, shown in FIG. 8, a third through hole penetrating through the insulating layer 102, the top silicon layer 103 and the first dielectric layer 401 is formed. The electrical connection material is filled in the third through hole to form a third conductive post 501. The third conductive post 501 is electrically connected to the first interconnection structure layer 405, A second wiring layer 502 is formed on the surface of the insulating layer, the second wiring layer 502 being electrically connected to the third conductive post 501,

The second redistribution layer 503 electrically connected to the second wiring layer 502 and the third conductive post 501 in sequence is formed on the surface of the insulating layer 102. The second redistribution layer 503 further includes the I/O pad 411.

The embodiments of the present disclosure further provide an integration structure for the control circuit and the BAW filter, which includes: a base, the base being provided with a control circuit and a first cavity; and a BAW resonating structure, an input electrode and an output electrode being arranged on a surface of the BAW resonating structure, the BAW resonating structure including a second cavity, and the surface of the BAW resonating structure facing towards the base such that the BAW resonating structure is bonded to the base and seals the first cavity; and the control circuit is electrically connected to the input electrode and the output electrode.

The integration structure according to the embodiments of the present disclosure implements the control on the BAW filter by forming the control circuit on the base, and thus may avoid the problems of the complex electrical connection process, large insertion loss and the like due to a fact that the existing B,AW filter is integrated to the PCB as a discrete device, has the high level of integration, and reduces the process cost

Referring to FIG, 7, the integration structure for the control circuit and the BAW filter according to the first embodiment of the present disclosure includes:

a base, the base being provided with a control circuit and a first cavity 402; and

a BAW resonating structure, an input electrode and an output electrode 302 being arranged on a surface of the BAW resonating structure, the BAW resonating structure including a second cavity 307, and the surface of the BAW resonating structure facing towards the base such that the BAW resonating structure is bonded to the base and seals the first cavity 402.

The control circuit is electrically connected to the input electrode and the output electrode,

In the embodiment, the base includes a substrate and a first dielectric layer 401 formed on the substrate, The substrate is an SOI substrate. The SOI substrate includes an insulating layer 102 and atop silicon layer 103 located on the insulating layer 102.

The control circuit includes a device structure and a first interconnection structure layer electrically connected to the device structure, The device structure includes an MOS switch. The MOS switch includes a source 201 arid a drain 202 formed in the top silicon layer 103 of the SOI substrate, and a gate dielectric layer 204 and a gate 203 formed on the top silicon layer 103.

The first interconnection structure layer is located on the first dielectric layer 401, and electrically connected to the input electrode and the output electrode 302. Specifically, the first interconnection structure layer includes a first conductive post 404 and a first wiring layer 405 that are electrically connected to the device structure in sequence. The first cavity 402 is formed in the first dielectric layer 401.

The BAW resonating structure includes a first support plate 301, a second support plate 302, a first electrode 303 and a second electrode 304 arranged between the first support plate 301 and the second support plate 302, and a piezoelectric layer 305 disposed between the first electrode 303 and the second electrode 304. The input electrode and the output electrode (not shown are arranged on an outer side of the first support plate 301. The input electrode and the output electrode are respectively and electrically connected to the first electrode 303 and the second electrode 304. Additionally, in order to ensure the normal work of the BAW filter, a silicon wafer 306 is disposed on an outer side of the second support plate 302. The second cavity 307 is provided on the silicon wafer 306. Optionally, both the input electrode and the output electrode include a pad.

In the embodiment, the integration structure further includes a first redistribution layer 406 and a first pad 407 that are formed on the base. The first pad 407 is electrically connected to the input electrode and the output electrode, such that the input electrode and the output electrode are electrically connected to the control circuit through the first pad 407 and the first redistribution layer 406.

The base and the BAW resonating structure are bonded through an annular adhesion structure 408. The adhesion structure 408 is disposed on the first redistribution layer 406 and at the periphery of the first cavity 402. Optionally, the adhesion structure 408 is a dry film or an adhesive layer formed through screen printing, or another chip connection film.

In the embodiment, the integration structure further includes a packaging layer 403, the packaging layer 403 covering the base and the BAW resonating structure.

In the embodiment, the integration structure further includes a third redistribution layer 409, electrically connected to the input electrode, the output electrode and the control circuit. Specifically, the third redistribution layer 409 is electrically connected to a second conductive post 410 penetrating through the packaging layer 403. The third redistribution layer 409 further includes an I/O pad 411.

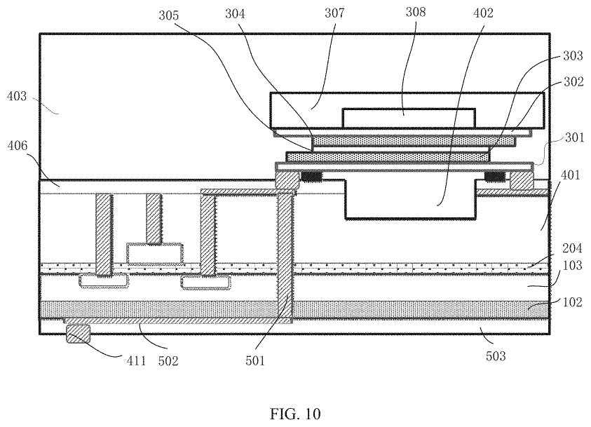

Referring to FIG. 10, the integration structure for the control circuit and the BAW filter according to the second embodiment of the present disclosure includes:

a base, the base being provided with a control circuit and a first cavity 402; and

a BAW resonating structure, an input electrode and an output electrode 302 being arranged on a surface of the B,AW resonating structure, the BAW resonating structure including a second cavity 307, and the surface of the BAW resonating structure facing towards the base such that the BAW resonating structure is bonded to the base and seals the first cavity 402.

The control circuit is electrically connected to the input electrode and the output electrode.

In the embodiment, the base includes a substrate and a first dielectric layer 401 formed on the substrate. The substrate is an SOI substrate. The SOI substrate includes an insulating layer 102 and a top silicon layer 103 located on the insulating layer 102.

The control circuit includes a device structure and a first interconnection structure layer electrically connected to the device structure. The device structure includes an MOS switch. The MOS switch includes a source 201 and a drain 202 formed in the top silicon layer 103 of the SOI substrate, and a gate dielectric layer 204 and a gate 203 formed on the top silicon layer 103.

The first interconnection structure layer is located on the first dielectric layer 401, and electrically connected to the input electrode and the output electrode 302. Specifically, the first interconnection structure layer includes a first conductive post 404 and a first wiring layer 405 that are electrically connected to the device structure in sequence. The first cavity 402 is formed in the first dielectric layer 401.

The BAW resonating structure includes a first support plate 301, a second support plate 302, a first electrode 303 and a second electrode 304 arranged between the first support plate 301 and the second support plate 302, and a piezoelectric layer 305 disposed between the first electrode 303 and the second electrode 304. The input electrode and the output electrode (not shown) are arranged on an outer side of the first support plate 301. The input electrode and the output electrode are respectively and electrically connected to the first electrode 303 and the second electrode 304. Additionally, in order to ensure the normal work of the BAW filter, a silicon wafer 306 is disposed on an outer side of the second support plate 302. The second cavity 307 is provided on the silicon wafer 306. Optionally, both the input electrode and the output electrode include a pad.

In the embodiment, the integration structure further includes a first redistribution layer 406 and a first pad 407 that are formed on the base. The first pad 407 is electrically connected to the input electrode and the output electrode, such that the input electrode and the output electrode are electrically connected to the control circuit through the first pad 407 and the first redistribution layer 406.

The base and the BAW resonating structure are bonded through an annular adhesion structure 408. The adhesion structure 408 is disposed on the first redistribution layer 406 and at the periphery of the first cavity 402. Optionally, the adhesion structure 408 is a dry film or an adhesive layer formed through screen printing, or another chip connection film.

In the embodiment, the integration structure further includes a packaging layer 403, the packaging layer 403 covering the base and the BAW resonating structure.

In the embodiment, the integration structure further includes a second redistribution layer 503 formed on a back of the base, the second redistribution layer 503 being electrically connected to the input electrode, the output electrode and the control circuit. Specifically, the second redistribution layer 503 is disposed on a surface of the insulating layer 102, and electrically connected to a third conductive post 501 penetrating through the base and a second wiring layer 502 disposed on the surface of the insulating layer. The third conductive post 501 is electrically connected to the first interconnection structure layer 405. The second redistribution layer 503 further includes the I/O pad 411.

The embodiments of the present disclosure have been described above, and the foregoing description is illustrative, not limiting, and not limited to the disclosed embodiments. Numerous modifications and changes will be apparent to those skilled in the art without departing from the scope and spirit of the illustrated embodiments.

1-27 (canceled)

28. An integration method for a control circuit and a bulk acoustic wave (BAW) filter, comprising:
providing a base, the base being provided with a control circuit;
forming a first cavity on the base;
providing a BAW resonating structure, an input electrode and an output electrode being arranged on a surface of the BAW resonating structure, and the BAW resonating structure comprising a second cavity;
facing the surface of the BAW resonating structure towards the base, such that the BAW resonating structure is bonded to the base and seals the first cavity; and
electrically connecting the control circuit to the input electrode and the output electrode.

29. The integration method according to claim 28, wherein the base comprises a substrate and a first dielectric layer formed on the substrate; and
forming the first cavity on the base comprises:
forming the first cavity in the first dielectric layer.

30. The integration method according to claim 29, wherein the substrate comprises one of a Silicon-on-Insulator (SOI) substrate, a silicon substrate, a germanium substrate, a germanium silicate substrate and a gallium arsenide substrate.

31. The integration method according to claim 29, wherein the control circuit comprises a device structure and a first interconnection structure layer electrically connected to the device structure, the first interconnection structure layer being located on the first dielectric layer, and electrically connected to the input electrode and the output electrode, and
wherein the device structure comprises a Metal Oxide Semiconductor (MOS) device.

32. The integration method according to claim 31, wherein electrically connecting the control circuit to the input electrode and the output electrode comprises:
after bonding the BAW resonating structure, electrically connecting the first interconnection structure layer to the input electrode and the output electrode; or
before bonding the BAW resonating structure, forming a first redistribution layer and a first pad on the first interconnection structure layer; and
after bonding the BAW resonating structure, electrically connecting the first pad to the input electrode and the output electrode, such that the input electrode and the output electrode are electrically connected to the control circuit through the first pad and the first redistribution layer.

33. The integration method according to claim 29, wherein facing the surface of the BAW resonating structure towards the base, such that the BAW resonating structure is bonded to the base and seals the first cavity comprises:
forming an adhesion structure on the surface of the base and at the periphery of the first cavity; and
adhering the BAW resonating structure to the base through the adhesion structure.

34. The integration method according to claim 33, wherein the adhesion structure comprises a dry film, and
wherein the first cavity is formed in the dry film by exposure and development.

35. The integration method according to claim 33, wherein the adhesion structure is formed by a patterned adhesive layer through screen printing.

36. The integration method according to claim 29, further comprising: forming a second redistribution layer on a back of the base, the second redistribution layer being electrically connected to the input electrode, the output electrode and the control circuit,
wherein the second redistribution layer comprises an Input/Output (I/O) pad.

37. The integration method according to claim 28, after the bonding, further comprising:
forming a packaging layer, the packaging layer covering the base and the BAW resonating structure; and
forming a third redistribution layer on the packaging layer, the third redistribution layer being electrically connected to the input electrode, the output electrode and the control circuit.

38. The integration method according to claim 28, wherein both the input electrode and the output electrode include a pad.

39. An integration structure for a control circuit and a Bulk Acoustic Wave (BAW) filter, comprising:
a base, the base being provided with a control circuit and a first cavity; and
a BAW resonating structure, an input electrode and an output electrode being arranged on a surface of the BAW resonating structure, the BAW resonating structure comprising a second cavity, and the surface of the BAW resonating structure facing towards the base such that the BAW resonating structure is bonded to the base and seals the first cavity,
wherein the control circuit is electrically connected to the input electrode and the output electrode.

40. The integration structure according to claim 39, wherein the base comprises a substrate and a first dielectric layer formed on the substrate; and the first cavity is formed in the first dielectric layer; or
the base and the BAW resonating structure are bonded through an adhesion structure, and the first cavity is formed in the adhesion structure.

41. The integration structure according to claim 40, wherein the adhesion structure is a dry film; and/or
the substrate comprises one of a Silicon-on-Insulator (SOI) substrate, a silicon substrate, a germanium substrate, a germanium silicate substrate and a gallium arsenide substrate.

42. The integration structure according to claim 40, wherein the control circuit comprises a device structure and a first interconnection structure layer electrically connected to the device structure, the first interconnection structure layer being located on the first dielectric layer, and electrically connected to the input electrode and the output electrode, and
wherein the device structure comprises a Metal Oxide Semiconductor (MOS) device.

43. The integration structure according to claim 42, wherein a first redistribution layer and a first pad are formed on the base, the first pad being electrically connected to the input electrode and the output electrode, such that the input electrode and the output electrode are electrically connected to the control circuit through the first pad and the first redistribution layer.

44. The integration structure according to claim 39, further comprising a second redistribution layer formed on a back of the base, the second redistribution layer being electrically connected to the input electrode, the output electrode and the control circuit,
wherein the second redistribution layer comprises an Input/Output (I/O) pad.

45. The integration structure according to claim 39, further comprising a packaging layer, the packaging layer covering the base and the BAW resonance structure.

46. The integration structure according to claim 45, further comprising a third redistribution layer formed on the packaging layer, the third redistribution layer being electrically connected to the input electrode, the output electrode and the control circuit.

47. The integration structure according to claim 39, wherein both the input electrode and the output electrode include a pad.
